(19) United States
(12) Patent Application Publication
(10) Pub. No.: US 2016/0247657 A1
(43) Pub. Date: Aug. 25, 2016

(54) MICRO-ELECTRON COLUMN HAVING NANO STRUCTURE TIP WITH EASILY ALIGNING

(71) Applicants: Ho Seob KIM, Incheon (KR); Tae Sik OH, Cheonam-si (KR); Dae Wook KIM, Seongnam-si (KR); Seung Jun AHN, Daejeon (KR); Hyung Woo KIM, Seoul (KR)

(72) Inventors: Ho Seob KIM, Incheon (KR); Tae Sik OH, Cheonam-si (KR); Dae Wook KIM, Seongnam-si (KR); Seung Jun AHN, Daejeon (KR); Hyung Woo KIM, Seoul (KR)

(21) Appl. No.: 14/631,729

(22) Filed: Feb. 25, 2015

(51) Int. Cl. H01J 37/063; H01J 37/10; H01J 37/147; H01J 37/065

(52) U.S. Cl. CPC H01J 37/063; H01J 37/065; H01J 37/10; H01J 37/1472

(57) ABSTRACT

Disclosed is a micro-electron column having nanostructure tips. The micro-electro column includes an electron emission source that is provided with a plurality of nanostructure tips and emits electrons, a source lens, a deflector, and a focusing lens. The nanostructure tips of the electron emission source spread over an area that is larger than that of an aperture of a first lens electrode of a source lens, which is nearest to the electron emission source.

### BACKGROUND OF THE INVENTION

1. Field of the Invention

The preset invention relates to a micro-electron column having nanostructure tips that have the form of a tube, pillar, or ingot, having a size of several or several tens of nanometers. More particularly, the present invention relates to a micro-electron column having nanostructure tips that easily emit electrons therefrom by creating an electric field when a voltage is applied thereto, that can be easily aligned with an electron lens component such as an aperture of an electron electrode, and that is convenient to use.

2. Description of the Related Art

A micro-electron column is based on an electron emission source and electronic optical components having micro-structures, which operate under the basic principle of a scanning tunneling microscope (STM), and was first introduced in the 1980s. The micro-electron column is formed by elaborately assembling micro-components together to minimize optical aberrations thus forming an improved electron column. When many microcolumns are arranged to form an array, they can be used in the structure of a multi-electron column having a series-connection or parallel-connection arrangement.

FIG. 1 is a view showing the structure of a micro-electron column and illustrates that an electron emission source, a source lens, a deflector, and an Einzel lens that serves as a focusing lens are aligned together to scan an electron beam.

Generally, a microcolumn, which is representative of micro-electron columns, includes an electron emission source 10 for emitting electrons, a source lens 20 for controlling the emitted electrons to form an effective electron beam B, a deflector 30 for deflecting the electron beam, and a focusing lens (Einzel lens) 40 for focusing the electron beam on a sample S.

The electron emission source is one of core elements in existing electron columns or electron microscopes. There are several types of electron emission sources, for example, a field emitter (FE), a thermal emitter (TE), and a thermal field emitter (TFE) all of which are also referred to as Schottky emitters. An ideal electron emission source requires stabilized electron emission, high brightness, a small size, low energy spreading and a long lifespan.

Electron columns are classified into single electron columns and multi-type electron columns. A single electron column includes one electron emission source and electron lenses for controlling an electron beam emitted from the electron emission source. A multi-type electron column includes electron lenses for controlling a plurality of electron beams emitted from a plurality of electron emission sources. Such multi-type electron columns may be classified into wafer-type electron columns, each including an electron emission source having a plurality of electron emission source tips provided in one layer such as a semiconductor wafer and an electron lens including stacked lens layers, each being provided with a plurality of apertures; combination type electron columns, each controlling electron beams, emitted from individual electron emission sources as in a single electron column, using a single lens layer having a plurality of apertures; and a scheme in which single electron columns each including one electron source and one lens are mounted and used in one housing. In the case of the combination-type electron columns, the electron emission source is divided into separate sources, and lenses are used in the same manner as the wafer-type electron columns.

The above-described micro-electron columns are important elements in various fields that use an electron beam, such as inspection instruments for inspecting semiconductor holes such as via holes or through holes. For example, the micro-electron columns are important parts in the fields of electron beam lithography, electron microscopes, etc.

Furthermore, equipment or apparatus using an electron beam or an electron column can exhibit maximum performance only when an electron emission source is accurately aligned with the center of the optical axis of electron lenses (in particular, a source lens). To this end, not only must the tips of the electron emission source be well aligned with the optical axis of the lenses, but the tip itself must also be fabricated or formed to be aligned with the optical axis. Furthermore, in the case in which the tip itself is not formed to be aligned with the optical axis, it is difficult to correct the misalignment. Although correction of the misalignment of the tip is possible, an additional component or control scheme is needed.

In particular, there is a growing need for various types of equipment using electron beams to rapidly and precisely fabricate, measure, and inspect miniaturized structures in step with the tendency toward small-sized components and use of a larger wafers in semiconductors, display equipment, etc. In order to improve productivity, there is an increasing need for a multi-type electron column in which several electron beams are operated at the same time, and thus an electron emission source suitable for a multi-type electron column is necessary.

Accordingly, there is the need for an electron emission source that fulfills the requirements of an electron emission source, can be well aligned, and is appropriate for use in a multi-type application.

### DOCUMENTS OF RELATED ART

### Patent Documents

(Patent Document 1) Korean Patent Application Publication No. 10-2010-0037095 (Apr. 8, 2010)

### SUMMARY OF THE INVENTION

Accordingly, the present invention has been made keeping in mind the above problems occurring in the prior art, and an object of the present invention is to provide a micro-electron column having nanostructure tips that can emit electrons at a low voltage unlike existing electron emission sources and that is easy to fabricate and use.

Another object of the present invention is to provide a micro-electron column having nanostructure tips that enables easy alignment between the nanostructure tips and an electron lens.

In order to accomplish the objects of the invention, one aspect provides a micro-electron column having an electron emission source, a source lens, a deflector, and a focusing lens, in which the electron emission source is provided with a plurality of nanostructure tips to emit electrons, and the nanostructure tips of the electron emission source are arranged to spread over an area that is larger than an aperture of a first lens electrode of the source lens, which is nearest to the electron emission source among lens electrodes of the source lens.

The nanostructure tips of the electron emission source may be aligned to cover the entire area of the aperture of the first lens electrode of the source lens, and the aperture of the first lens electrode may be smaller than that of a second lens electrode which is second nearest to the electron emission source among the lens electrodes of the source lens.

The aperture of the second lens electrode is five or more times larger than that of the first lens electrode.

The micro-electron column may further include an induction electrode disposed between the electron emission source and the source lens to guide electrons emitted from the electron emission source to enter into the aperture of the first lens electrode of the source lens.

In order to accomplish the objects of the invention, another aspect provides a multi-type micro-electron column in which the micro-electron column according to the former aspect forms a unit micro-electron column.

The micro-electron column having nanostructure tips according to one aspect of the invention has advantages in that it can emit electrons at a low voltage unlike existing electron emission sources and it is easy to fabricate and use.

The micro-electron column having nanostructure tips according to one aspect of the invention has an advantage of enabling the nanostructure tips to be easily aligned with an electron lens.

According to the micro-electron column having nanostructure tips according to one aspect of the invention, multiple electron emission sources can be fabricated on one substrate such as a silicon wafer. Therefore, fabrication cost is reduced and a multi-type micro-electron column can be easily fabricated.

When the electron emission sources fabricated on a wafer like electron lenses are formed on a wafer, they can operate as a multi-type electron emission source as it is. Alternatively, the electron emission sources fabricated on a wafer are first cut into discrete electron emission sources, and then the discrete electron emission sources, fabricated as such, may be assembled to form a multi-type micro-electron column. In this way, a multi-type micro-electron column can be easily fabricated.

### BRIEF DESCRIPTION OF THE DRAWINGS

FIG. 1 is a cross-sectional view illustrating the conceptual structure of a microcolumn;

FIGS. 2A and 2B are respectively a plan view and a cross-sectional view illustrating a microcolumn having nanostructure tips according to one embodiment of the present invention;

FIGS. 3A and 3B are respectively a plan view and a cross-sectional view that illustrate a multi-type microcolumn;

FIGS. 4A and 4B are respectively a plan view and a cross-sectional view that illustrate a microcolumn having nanostructure tips according to another embodiment of the present invention; and

FIGS. 5A and 5B are respectively a plan view and a cross-sectional view that illustrate a microcolumn having nanostructure tips according to a further embodiment of the present invention.

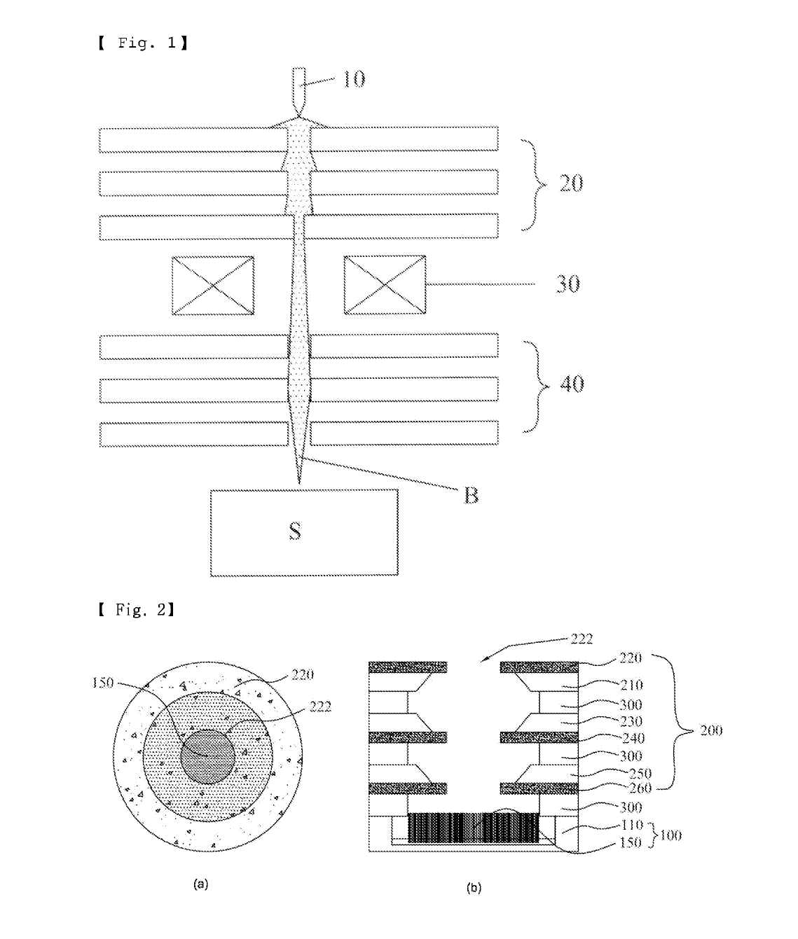

### DETAILED DESCRIPTION OF THE INVENTION

A feature of the present invention to achieve the above-described objects is forming nanostructure tips of an electron emission source to spread over an area that is broader than the area of a first lens electrode of a source lens, which is nearest to the electron emission source among lens electrodes of the source lens.

Hereinafter, a micro-electron column having nanostructure tips according to the present invention will be described with reference to the accompanying drawings.

FIGS. 2A and 2B illustrate a micro-electron column having nanostructure tips according to one embodiment of the present invention. Specifically, FIG. 2A is a plan view illustrating a state in which the nanostructure tips are located in the lowest layer, and FIG. 2B is a cross-sectional view illustrating the same state.

The micro-electron column according to the present embodiment has a structure in which a source lens 200 is arranged on an electron emission source 100 provided with a plurality of nanostructure tips 150.

The source lens 200 is composed of three electrode layers 220, 240, and 260. The respective electrode layers 220, 240, and 260 are highly doped portions within silicon layers 210, 230, and 250. The respective electrode layers formed of highly doped regions are formed like the electron emission source in a silicon substrate, forming a membrane. An aperture 222 is formed at the center of the membrane so that an electron beam can pass through the aperture 222. Lower electrode layers 250 and 260 are referred to as an extractor in a microcolumn and promote emission of electrons from the nanostructure tips 150 of the electron emission source 100. Middle electrode layers 230 and 240 are referred to as an accelerator and accelerate emitted electrons. Upper electrode layers 210 and 220 are referred to as a limiting aperture and form an effective electron beam to limit electrons. That is, the source lens 200 primarily functions to shape an electron beam from electrons emitted from the electron emission source and secondarily performs focusing or the like. Alternatively, some layers, such as the layers 210, 230, and 250, may be removed.

In the source lens 200, an insulating layer 300 such as a Pyrex substrate is interposed between the respective electrode layers for electrical insulation. To insulate the extractor and the electron emission source from each other, another insulating layer 300 such as a Pyrex substrate is interposed between the extractor and the electron emission source.

FIGS. 2A and 2B illustrate a micro-electron column having an electron emission source according to one embodiment of the present invention. A source lens can be combined with a separate electron emission source. However, when the source lens is formed to be stacked on a silicon substrate on which the electron emission source is formed, using a semiconductor fabrication process, fabrication and alignment of the source lens and the electron emission source become easier.

According to the present embodiment of the present invention, the nanostructure tips 150 are arranged within a tip base 110 made of silicon, thus forming the electron emission source 100. The nanostructure tip 150 has the form of a tube, pillar, or ingot with several or several tens of nanometers, such as a carbon nanotube (CNT), a ZnO nanotube, a ZnO nanorod, a ZnO nanopillar, a ZnO nanowire, or a ZnO nanoparticle. When a voltage is applied to the nanostructure tip 150, an intensive electric field is formed at a tip portion, so that electrons can be easily emitted.

As illustrated in FIGS. 2A and 2B, the nanostructure tips 150 are formed to spread over an area that is larger than the size of an aperture 222 of a lens electrode of a source lens. In the plan view of FIG. 2A, the nanostructure tips 150 partially overlap an electrode layer 220. Since the optical axis of the electron emission source 100 agrees with the central axis of the apertures of the source lenses and the nanostructure tips 150 are formed to be larger than the aperture 222 of the source lens 220, alignment of the electron emission source 100 and the source lens 200 can be easily made.

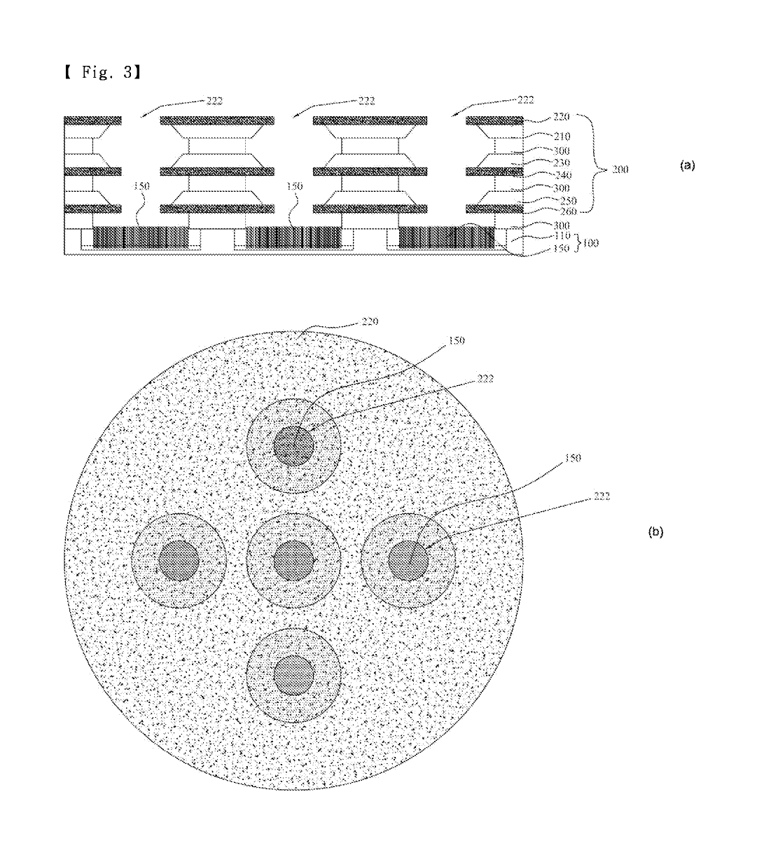

FIGS. 3A and 3B illustrate a multi-type micro-electron column. In FIGS. 3A and 3B, a micro-electron column is aligned in the same manner as in FIGS. 2A and 2B. Since the electron emission source 100 according to the present invention can be provided with a plurality of nanostructure tips 150, the nanostructure tips 150 can be arranged in the same manner as electron lenses (particularly, a source lens) shown in FIGS. 2A and 2B.

When one unit to create an electron beam using electrons emitted from a nanostructure tip is referred to as a unit electron column, FIGS. 3A and 3B illustrate a multi-type micro-electron column including five unit electron columns. In FIGS. 3A and 3B, all of the nanostructure tips are formed in one substrate. Within the structure, all the nanostructure tips may be collectively applied with a same voltage or individually applied with different voltages. When it is necessary for the unit electron columns to be applied with respective different voltages, the nanostructure tips are applied with respective different voltages by unit electron columns. Alternatively, the apertures of the electrode layer that is nearest to the respective electron emission sources may be applied with respective different voltages by unit electron columns. That is, it is possible to control application of a voltage to each unit electron column by using a voltage difference between the nanostructure tip and the electrode layer nearest to the electron emission source in the unit electron column. In FIGS. 3A and 3B, the electrode layers 220 are formed in one layer (or plate) and the apertures 222 are divided into unit electron columns. However, the electrode layers 220, 240, and 260 may also be divided by unit electron column like the nanostructure tips so that the apertures 222 can be individually applied with a voltage. This structure can be fabricated using a conventional method of fabricating a multi-type column disclosed in WO2006/004374 (Jan. 12, 2006).

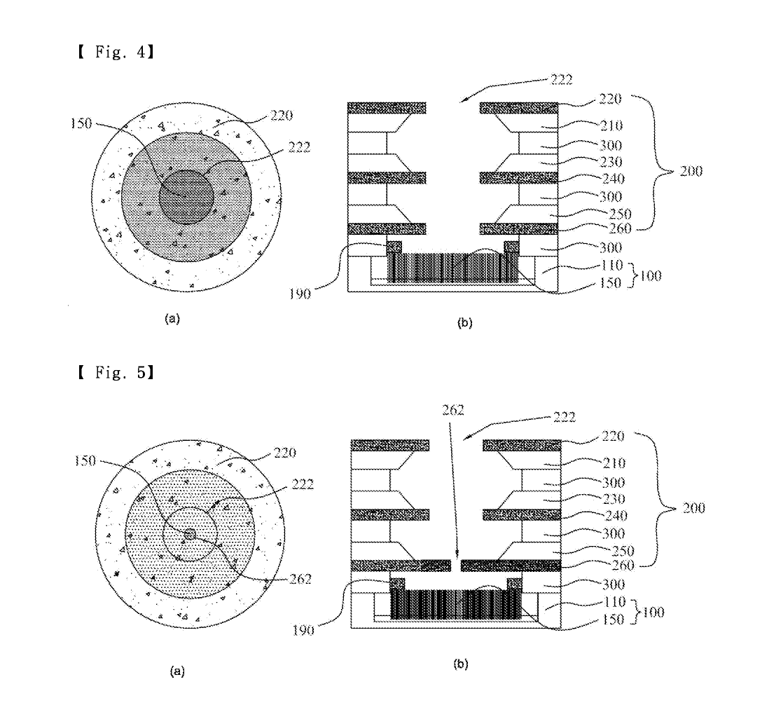

FIGS. 4A and 4B are respectively a plan view and a cross-sectional view illustrating a micro-electron column having nanostructure tips according to another embodiment of the present invention. Compared with the micro-electron column shown in FIGS. 2A and 2B, the micro-electron column of FIGS. 4A and 4B additionally includes an induction electrode 190 disposed between an electron emission source 100 and a source lens 200. The induction electrode 190 guides electrons generated by the nanostructure tips 150 so that the electrons can well enter into the aperture 222 of the source lens 200. The induction electrode 190 has an aperture larger than that of the source lens 222. The induction electrode 190 is applied with a second negative voltage the absolute value of which is smaller than that of a first negative voltage applied to the nanostructure tip 150.

FIGS. 5A and 5B are respectively a plan view and a cross-sectional view illustrating a micro-electron column having nanostructure tips according to a further embodiment of the present invention. When the micro-electron column of FIGS. 5A and 5B is compared with the micro-electron columns of FIGS. 2A, 2B, 4A and 4B, the aperture 262 of an electrode layer 260, through which electrons emitted from an electron emission source first passes within a source lens, is significantly smaller than those of the other electrode layers 240 and 220 of the source lens. The purpose of making the aperture 262 of the electrode layer 260 smaller than the apertures of the other electrode layers is to select only electrons with good linearity along the optical axis at the center of the apertures of the source lenses 200 among electrons emitted from the electron emission sources. With this structure, although the number of electrons that pass through the source lenses is reduced due to the small aperture, only electrons with good linearity along the optical axis can be selected. Therefore, focusing is improved, and the size of a spot of an electron beam that reaches a sample is reduced. This results in an improvement in resolution. The aperture 262 of the electrode layer 260 is smaller than the apertures 222 of the other electrode layers 240 and 220 within the source lenses 200. In particular, the aperture 262 of the electrode layer 260 may be ⅕ times smaller (or much smaller) than the aperture of the next electrode layer (second electrode layer) of the source lens. The aperture of the next electrode layer (third electrode layer) or an electrode layer that is much farther from the electron emission source than the third electrode layer may be smaller than the aperture of the second electrode layer, if needed. Therefore, the aperture 262 of the electrode layer (first electrode layer) 260 is preferably smaller than the aperture of the second electrode layer. The structure of the embodiment of FIGS. 5A and 5B can be applied to all the embodiments of FIGS. 2A, 2B, 4A and 4B.

Although the structure of FIGS. 5A and 5B includes the induction electrode 190, the induction electrode 190 may be removed as in the embodiment of FIGS. 2A and 2B as necessary. That is, the induction electrode 190 may be optional.

According to the present invention, preferably, a plurality of nanostructure tips 150 is arranged to form an array. In this case, the contour of the array has the same shape as the aperture of an electron lens and the area of the array is larger than that of the aperture of the electron lens. That is, when the aperture of an electron lens has a circular shape, the contour of an array of the nanostructure tips has a circular shape. Likewise, when the aperture of an electron lens has a polygonal shape, the contour of an array of the nanostructure tips has the same polygonal shape. As long as the size of an array of the nanostructure tips 150 is larger than that of the aperture of an electron lens, the shape of an array of the nanostructure tips 150 may not be limited.

A multi-type micro-electron column can be fabricated using any of the micro-electron columns according to the embodiments of FIGS. 2A, 2B, 4A, 4B, 5A, and 5B.

1. A micro-electron column having nanostructure tips, comprising:
an electron emission source that is provided with a plurality of nanostructure tips and emits electrons;
a source lens;
a deflector; and
a focusing lens,
wherein the nanostructure tips of the electron emission source spread over an area that is larger than that of an aperture of a first lens electrode of a source lens, which is nearest to the electron emission source.

2. The micro-electron column according to claim 1, wherein
the nanostructure tips of the electron emission source are aligned to cover the entire area of the aperture of the first lens electrode of the source lens, and wherein the aperture of the first lens electrode of the source lens is smaller than an aperture of a second lens electrode of the source lens, which is second nearest to the electron emission source.

3.-4. (canceled)

5. The micro-electron column according to claim 2, wherein
the aperture of the second lens electrode is five or more times larger than that of the first lens electrode.

6. The micro-electron column according to claim 1, further comprising an induction electrode that is disposed between the electron emission source and the source lens and that guides electrons emitted from the electron emission source to well enter into the aperture of the first lens electrode of the source lens.

7. The micro-electron column according to claim 2, further comprising an induction electrode that is disposed between the electron emission source and the source lens and that guides electrons emitted from the electron emission source to well enter into the aperture of the first lens electrode of the source lens.

8. The micro-electron column according to claim 5, further comprising an induction electrode that is disposed between the electron emission source and the source lens and that guides electrons emitted from the electron emission source to well enter into the aperture of the first lens electrode of the source lens.

9. A multi-type micro-electron column in which one micro-electron column according to claim 1 forms a unit electron column.

10. A multi-type micro-electron column in which one micro-electron column according to claim 2 forms a unit electron column.

11. A multi-type micro-electron column in which one micro-electron column according to claim 5 forms a unit electron column.

12. A multi-type micro-electron column in which one micro-electron column according to claim 6 forms a unit electron column.

13. A multi-type micro-electron column in which one micro-electron column according to claim 7 forms a unit electron column.

14. A multi-type micro-electron column in which one micro-electron column according to claim 8 forms a unit electron column.
